(19) United States
(12) Patent Application Publication
(10) Pub. No.: US 2024/0379524 A1
(43) Pub. Date: Nov. 14, 2024

(54) SEMICONDUCTOR PACKAGES AND SUBSTRATES FOR PACKAGES

(71) Applicant: SAMSUNG ELECTRONICS CO., LTD., Suwon-si (KR)

(72) Inventor: Daehun Lee, Suwon-si (KR)

(21) Appl. No.: 18/593,359

(22) Filed: Mar. 1, 2024

(30) Foreign Application Priority Data
May 9, 2023 (KR) 10-2023-0059809

(51) Int. Cl. H01L 23/498; H01L 23/00; H01L 25/10; H01L 25/16

(52) U.S. Cl. CPC H01L 23/49838; H01L 23/49811; H01L 25/16; H01L 28/40; H01L 24/16; H01L 24/32; H01L 24/48; H01L 24/73; H01L 25/105; H01L 2224/16227; H01L 2224/32225; H01L 2224/48227; H01L 2224/73265

(57) ABSTRACT

An example semiconductor package includes: a substrate that includes a first surface and a second surface disposed in an opposite direction of the first surface; a semiconductor chip that is disposed at the first surface of the substrate; and an electronic element that is disposed at at least one surface of the substrate. The substrate includes a first element pad disposed at one surface of the at least one surface, a second element pad disposed at a same surface as the first element pad, a first connection pillar extending from the first element pad, a second connection pillar extending from the second element pad, and the electronic element is connected to the first connection pillar and the second connection pillar.

### CROSS-REFERENCE TO RELATED APPLICATION

This application claims priority to and the benefit of Korean Patent Application No. 10-2023-0059809 filed in the Korean Intellectual Property Office on May 9, 2023, the entire contents of which are incorporated herein by reference.

### BACKGROUND

A semiconductor package implements an integrated circuit chip as a form suitable for use in an electronic product. Generally, the semiconductor package is made by mounting a semiconductor chip on a substrate such as a printed circuit board (PCB) or the like. A plurality of semiconductor chips may be mounted in one semiconductor package. The plurality of semiconductor chips may have various functions. A package on package structure may be used in which one package is combined with another package. Various components other than the semiconductor chip may be coupled to the substrate of the semiconductor package. For example, a passive element such as a capacitor or the like may be coupled to the substrate. The passive element may perform various functions by being coupled to the inside of the substrate, an upper surface of the substrate, a lower surface of the substrate, or the like.

### SUMMARY

The present disclosure relates to a semiconductor package and a substrate for the package in which an electronic element (or an electronic device) may be effectively mounted so that a defect or a damage around the electronic element is prevented.

However, problems to be solved by the present disclosure are not limited to the above-described problem and may be variously extended in a range of technical ideas included in the present disclosure.

In some implementations, a semiconductor package includes: a substrate that includes a first surface and a second surface disposed in an opposite direction of the first surface; a semiconductor chip that is disposed at the first surface of the substrate; and an electronic element that is disposed at at least one surface of the substrate. The substrate may include a first element pad disposed at the at least one surface, a second element pad disposed at the same surface as the first element pad, a first connection pillar extending from the first element pad, and a second connection pillar extending from the second element pad, and the electronic element may be connected to the first connection pillar and the second connection pillar.

The semiconductor package may further include an adhesive layer disposed at a region where the electronic element and the first connection pillar are connected and a region where the electronic element and the second connection pillar are connected.

The adhesive layer may be disposed at at least a portion of a region where the electronic element and the first connection pillar face each other and at least a portion of a region where the electronic element and the second connection pillar face each other. Each of the first connection pillar and the second connection pillar may be provided with two connection pillars.

The two first connection pillars and the two second connection pillars may be disposed to be spaced apart from each other in a direction crossing a direction in which the first element pad and the second element pad face each other.

The substrate may further include a third element pad disposed at the same surface as the first element pad, a fourth element pad disposed at the same surface as the first element pad, a third connection pillar extending from the third element pad, and a fourth connection pillar extending from the fourth element pad.

At least some regions of the third element pad and the fourth element pad may be disposed at a region between the first element pad and the second element pad.

A direction in which the third element pad and the fourth element pad face each other may cross a direction in which the first element pad and the second element pad face each other.

Each of the third connection pillar and the fourth connection pillar may be provided with two connection pillars.

The two third connection pillars and the two fourth connection pillars may be disposed to be spaced apart from each other in a direction crossing a direction in which the third element pad and the fourth element pad face each other.

A height at which the second connection pillar extends, a height at which the third connection pillar extends, and a height at which the fourth connection pillar extends may correspond to a height at which the first connection pillar extends.

Each of the height at which the first connection pillar extends, the height at which the second connection pillar extends, the height at which the third connection pillar extends, and the height at which the fourth connection pillar extends may be 40 μm to 80 μm.

The substrate may further include a third element pad disposed between the first element pad and the second element pad and a third connection pillar extending from the third element pad.

In some implementations, a semiconductor package includes: a substrate; a semiconductor chip disposed at an upper surface of the substrate; and an upper electronic element disposed at the upper surface of the substrate. The substrate may include a first element pad disposed at the upper surface, a second element pad disposed at the upper surface, a third element pad disposed at the upper surface, a fourth element pad disposed at the upper surface, and a connection pillar extending from the first element pad, the second element pad, the third element pad, and the fourth element pad, and the upper electronic element may be connected to the connection pillar.

The semiconductor package may further include an adhesive layer disposed at a region where the upper electronic element and the connection pillar are connected.

The connection pillar may be provided with the same material as the first element pad, the second element pad, the third element pad, and the fourth element pad.

A direction in which the first element pad and the second element pad face each other may cross a direction in which the third element pad and the fourth element pad face each other.

In some implementations, a substrate for the package includes: an upper pad connecting a semiconductor chip; and an element pad connecting an electronic element.

The element pad may include a first element pad, a second element pad disposed at the same surface as the first element pad, a first connection pillar extending from the first element pad, and a second connection pillar extending from the second element pad.

The substrate may further include: a third element pad disposed at the same surface as the first element pad; a fourth element pad disposed at the same surface as the first element pad; a third connection pillar extending from the third element pad; and a fourth connection pillar extending from the fourth element pad.

A direction in which the first element pad and the second element pad face each other may cross a direction in which the third element pad and the fourth element pad face each other.

In some implementations, an electronic element may be effectively mounted so that a defect or a damage around the electronic element is prevented.

### BRIEF DESCRIPTION OF THE DRAWINGS

FIG. 1 is a cross-sectional view of an example of a semiconductor package.

FIG. 2 is an example plane view of the semiconductor package in FIG. 1 with a molding layer omitted.

FIG. 3 is an example enlarged view of a region A in FIG. 2.

FIG. 4 is a view showing an example region where an upper electronic element (or an upper electronic device) is omitted so that an upper element pad is disposed on an upper surface of a substrate.

FIG. 5 is an example plane view of the upper element pad of FIG. 4.

FIG. 6 is a view illustrating an example of a process in which the upper electronic element is connected to a connection pillar.

FIG. 7 is a view illustrating an example state in which the upper electronic element is connected to the connection pillar.

FIG. 8 is an enlarged view of an example region where the upper electronic element and the connection pillar are connected.

FIGS. 9A and 9B are views illustrating an example of a process of forming the connection pillar at the upper element pad.

FIGS. 10A and 10B are views illustrating another example of a process of forming the connection pillar at the upper element pad.

FIG. 11 is an example bottom view of the upper electronic element.

FIG. 12 is an example view showing the upper element pad and the connection pillar.

FIG. 13 is another example view showing the upper element pad and the connection pillar.

FIG. 14 is another example bottom view of the upper electronic element.

FIG. 15 is another example view showing the upper element pad and the connection pillar.

FIG. 16 is another example view showing the upper element pad and the connection pillar.

FIG. 17 is another example view showing the upper element pad and the connection pillar.

FIG. 18 is a cross-sectional view of an example of a semiconductor package.

FIG. 19 is a cross-sectional view of another example of a semiconductor package.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

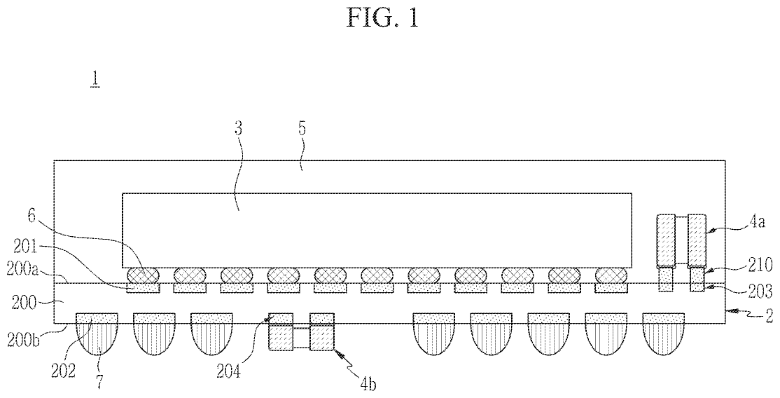

FIG. 1 is a cross-sectional view of an example of a semiconductor package.

Referring to FIG. 1, the semiconductor package 1 includes a substrate 2, a semiconductor chip 3, electronic elements (or electronic devices) 4a and 4b, and a molding layer 5.

The substrate 2 connects the semiconductor chip 3 and the like to the outside of the substrate 2. The substrate 2 includes a printed circuit board, a redistribution substrate, or the like. The substrate 2 has a first surface and a second surface disposed opposite each other in opposite directions. FIG. 1 shows a case where the first surface of the substrate 2 faces upward and the second surface of the substrate 2 faces downward. Hereinafter, the first surface of the substrate 2 is referred to as an upper surface of the substrate 2, and the second surface of the substrate 2 is referred to as a lower surface of the substrate 2. In addition, a direction in which the upper and lower surfaces are spaced apart is referred to as an up and down direction.

The substrate 2 includes a substrate body 200, an upper pad 201, a connection pad 202, and element pads 203 and 204.

The substrate body 200 may include an insulating material. The insulating material may include a thermosetting resin such as an epoxy resin or the like or a thermoplastic resin such as polyimide or the like. In addition, the insulating material may be impregnated with a reinforcing material such as glass fiber or inorganic filler. For example, the insulating material may include prepreg, Ajinomoto build-up film (ABF), FR-4, a bismaleimide triazine (BT) resin, or the like. A wiring structure or the like may be disposed in an inner region of the substrate body 200. The substrate body 200 has a first surface 200a and a second surface 200b disposed to face each other in opposite directions. In order to correspond to the substrate 2, the first surface 200a of the substrate body 200 may be an upper surface 200a of the substrate body 200 and the second surface 200b of the substrate body 200 may be a lower surface 200b of the substrate body 200. A passivation layer may be disposed at the upper surface 200a and the lower surface 200b of the substrate body 200. The passivation layer may be formed through a solder resist or the like.

The upper pad 201 is disposed at an upper end portion of the substrate body 200.

The upper pad 201 may be provided to be exposed to an outer space of the substrate 2. The upper pad 201 is provided with a conductive material. The upper pad 201 may be provided with a metallic material. For example, the upper pad 201 may be provided with copper (Cu), silver (Ag), palladium (Pd), aluminum (AI), nickel (Ni), titanium (Ti), gold (Au), platinum (Pt), an alloy thereof, or the like. A plurality of upper pads 201 may be provided. The plurality of upper pads 201 may be disposed in a lattice structure.

The connection pad 202 is disposed at a lower end portion of the substrate body 200. The connection pad 202 is provided to be exposed to an outer space of the substrate 2. The connection pad 202 is provided with a conductive material. The connection pad 202 may be provided with a metallic material. For example, the connection pad 202 may be provided with copper (Cu), silver (Ag), palladium (Pd), aluminum (AI), nickel (Ni), titanium (Ti), gold (Au), platinum (Pt), an alloy thereof, or the like. A plurality of connection pads 202 may be provided. A connection terminal 7 may be coupled to the connection pad 202. The connection terminal 7 may be a solder ball or the like.

The element pads 203 and 204 include the upper element pad 203 and the lower element pad 204.

The upper element pad 203 is disposed at an upper end portion of the substrate body 200. The upper element pad 203 may be provided to be exposed to an outer space of the substrate 2. The upper element pad 203 is provided with a conductive material. The upper element pad 203 may be provided with a metallic material. For example, the upper element pad 203 may be provided with copper (Cu), silver (Ag), palladium (Pd), aluminum (AI), nickel (Ni), titanium (Ti), gold (Au), platinum (Pt), an alloy thereof, or the like.

The lower element pad 204 is disposed at a lower end portion of the substrate body 200. The lower element pad 204 may be provided to be exposed to an outer space of the substrate 2. The lower element pad 204 is provided with a conductive material. The lower element pad 204 may be provided with a metallic material. For example, the lower element pad 204 may be provided with copper (Cu), silver (Ag), palladium (Pd), aluminum (Al), nickel (Ni), titanium (Ti), gold (Au), platinum (Pt), an alloy thereof, or the like.

The semiconductor chip 3 may be disposed at an upper surface of the substrate 2. The semiconductor chip 3 may include a logic semiconductor chip, a system on chip, or the like. The semiconductor chip 3 is connected to the upper pad 201. A chip terminal 6 may be disposed at a lower surface of the semiconductor chip 3 so that the chip terminal 6 is connected to the upper pad 201. The chip terminal 6 may be a solder bump, a solder ball, or the like.

The electronic elements 4a and 4b are disposed at at least one of the upper and lower surfaces of the substrate 2. Each of the electronic elements 4a and 4b may be a passive element. Each of the electronic elements 4a and 4b may be a capacitor. The capacitor may be a multi-layer ceramic capacitor (MLCC). The electronic elements 4a and 4b may include the upper electronic element 4a and the lower electronic element 4b.

The upper electronic element 4a is disposed at the upper surface of the substrate 2. The upper electronic element 4a may be connected to the upper element pad 203. The lower electronic element 4b is disposed at the lower surface of the substrate 2. The lower electronic element 4b may be connected to the lower element pad 204.

The molding layer 5 may be formed at the upper surface of the substrate 2. The molding layer 5 may be formed to surround the outside of the semiconductor chip 3. In addition, the molding layer 5 may be formed to surround the outside of the upper electronic element 4a. The molding layer 5 functions to protect the semiconductor chip 3 and the like from external impact, heat, and the like. The molding layer 5 may include an insulating polymer material such as an epoxy molding compound (EMC). The molding layer 5 may include a thermosetting resin such as an epoxy resin, a thermoplastic resin such as polyimide, a resin including a reinforcing material such as a filler included therein, or the like. For example, the molding layer 5 may include Ajinomoto build-up film (ABF), FR-4, a bismaleimide triazine (BT) resin, or the like.

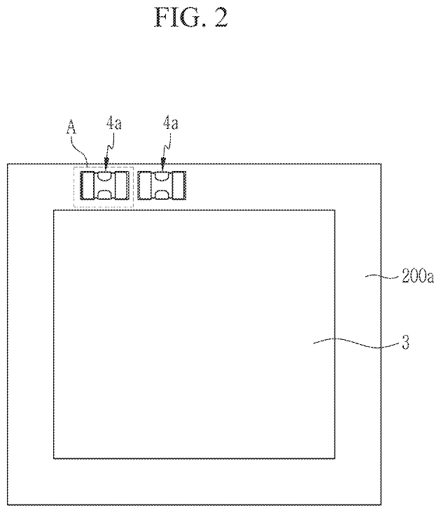

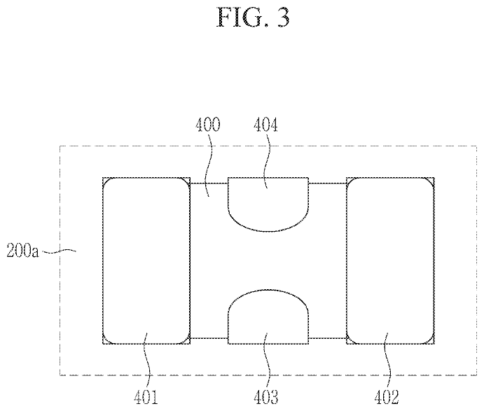

FIG. 2 is an example plane view of the semiconductor package in FIG. 1 with the molding layer omitted, and FIG. 3 is an example enlarged view of a region A in FIG. 2.

Referring to FIGS. 2 and 3, the upper electronic element 4a is provided as a capacitor to be disposed at the upper surface of the substrate 2.

The upper electronic element 4a includes a body 400, a first electrode 401, a second electrode 402, a third electrode 403, and a fourth electrode 404. The upper electronic element 4a may be a 3-terminal capacitor.

The body 400 may be provided with a dielectric material. An internal electrode made of a conductive material may be disposed inside the body 400.

The first electrode 401, the second electrode 402, the third electrode 403, and the fourth electrode 404 are attached to an outer surface of the body 400. The first electrode 401, the second electrode 402, the third electrode 403, and the fourth electrode 404 are provided with a conductive material. The first electrode 401, the second electrode 402, the third electrode 403, and the fourth electrode 404 may be provided with a metallic material.

The first electrode 401 and the second electrode 402 may be disposed to face each other with the body 400 interposed therebetween. The third electrode 403 and the fourth electrode 404 may be disposed to face each other with the body 400 interposed therebetween. A direction in which the first electrode 401 and the second electrode 402 face each other and a direction in which the third electrode 403 and the fourth electrode 404 face each other may cross each other. The direction in which the first electrode 401 and the second electrode 402 face each other and the direction in which the third electrode 403 and the fourth electrode 404 face each other may be disposed on a plane intersecting an up and down direction. At least some regions of the first electrode 401, the second electrode 402, the third electrode 403, and the fourth electrode 404 may be disposed at a bottom surface of the body 400 to be provided so as to vertically face the upper surface of the substrate 2.

The upper element pad 203 is disposed adjacent to the upper pad 201. Accordingly, the upper electronic element 4a may be disposed adjacent to the semiconductor chip 3 so that an operation characteristic of the upper electronic element 4a is improved.

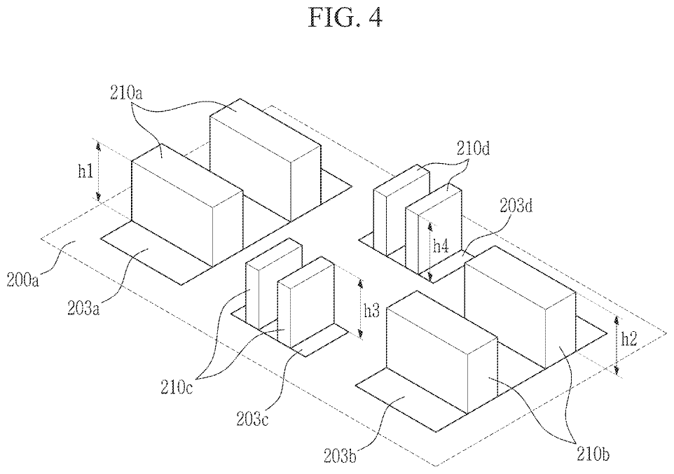

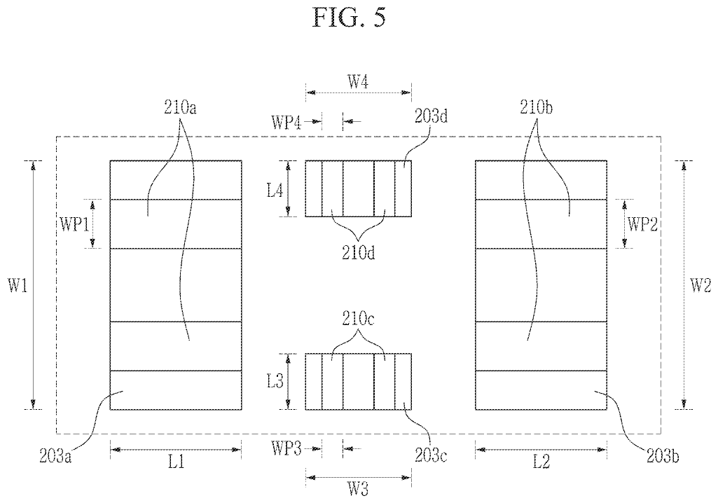

FIG. 4 is a view showing an example region where the upper electronic element (or an upper electronic device) is omitted so that the upper element pad is disposed on an upper surface of the substrate, and FIG. 5 is an example plane view of the upper element pad of FIG. 4.

Referring to FIGS. 4 and 5, the upper element pad 203 includes a first element pad 203a, a second element pad 203b, a third element pad 203c, and a fourth element pad 203d.

The first element pad 203a and the second element pad 203b are spaced apart from each other to be disposed facing each other. The first element pad 203a and the second element pad 203b have a predetermined length in directions facing each other. The first element pad 203a and the second element pad 203b have a predetermined width in a direction crossing a direction facing each other. A length L1 of the first element pad 203a may correspond to a length L2 of the second element pad 203b. A width W1 of the first element pad 203a may correspond to a width W2 of the second element pad 203b.

The third element pad 203c and the fourth element pad 203d are spaced apart from each other to be disposed facing each other. A direction in which the first element pad 203a and the second element pad 203b face each other and a direction in which the third element pad 203c and the fourth element pad 203d face each other may cross each other. The third element pad 203c and the fourth element pad 203d have a predetermined length in directions facing each other. The third element pad 203c and the fourth element pad 203d have a predetermined width in a direction crossing a direction facing each other. A length L3 of the third element pad 203c may correspond to a length L4 of the fourth element pad 203d. A width W3 of the third element pad 203c may correspond to a width W4 of the fourth element pad 203d.

At least some regions of the third element pad 203c and the fourth element pad 203d may be disposed at a region between the first element pad 203a and the second element pad 203b. For example, the third element pad 203c and the fourth element pad 203d may be disposed at a region between the first element pad 203a and the second element pad 203b.

An upper surface of the first element pad 203a may be coplanar with the upper surface 200a of the substrate body 200 adjacent to the first element pad 203a. An upper surface of the second element pad 203b may be coplanar with the upper surface 200a of the substrate body 200 adjacent to the second element pad 203b. An upper surface of the third element pad 203c may be coplanar with the upper surface 200a of the substrate body 200 adjacent to the third element pad 203c. An upper surface of the fourth element pad 203d may be coplanar with the upper surface 200a of the substrate body 200 adjacent to the fourth element pad 203d.

A connection pillar 210 is coupled to the upper element pad 203. The connection pillar 210 may extend in an up and down direction (or a vertical direction) from the upper element pad 203. The connection pillar 210 is provided with a conductive material. The connection pillar 210 may be provided with a metallic material. For example, the connection pillar 210 may be provided with copper (Cu), silver (Ag), palladium (Pd), aluminum (Al), nickel (Ni), titanium (Ti), gold (Au), platinum (Pt), an alloy thereof, or the like. A material of the connection pillar 210 may be the same as or different from that of the upper element pad 203.

The connection pillar 210 includes a first connection pillar 210a, a second connection pillar 210b, a third connection pillar 210c, and a fourth connection pillar 210d.

The first connection pillar 210a is coupled to the first element pad 203a. The first connection pillar 210a extends by a predetermined height in an up and down direction from the first element pad 203a. A height h1 of the first connection pillar 210a may be 40 μm to 80 μm. The first connection pillar 210a has a predetermined width in a width direction of the first element pad 203a. A width WP1 of the first connection pillar 210a is provided smaller than the width W1 of the first element pad 203a. The width WP1 of the first connection pillar 210a may be equal to or greater than ⅕ of the width W1 of the first element pad 203a. A width WP1 of the first connection pillar 210a may be greater than or equal to 106 μm.

Two first connection pillars 210a may be provided. In this case, the width WP1 of the first connection pillar 210a may be provided to be less than ½ of the width W1 of the first element pad 203a, so that the two first connection pillars 210a are disposed to be spaced apart from each other in the direction of the width W1 of the first element pad 203a.

The first connection pillar 210a has a predetermined length in a direction of the length L1 of the first element pad 203a. A length of the first connection pillar 210a may be equal to the length L1 of the first element pad 203a. In addition, the length of the first connection pillar 210a may be smaller than the length L1 of the first element pad 203a.

The second connection pillar 210b is coupled to the second element pad 203b. The second connection pillar 210b extends by a predetermined height in an up and down direction from the second element pad 203b. A height h2 of the second connection pillar 210b may be 40 μm to 80 μm. The height h2 of the second connection pillar 210b may correspond to the height h1 of the first connection pillar 210a. The second connection pillar 210b has a predetermined width in a direction of the width W2 of the second element pad 203b. A width WP2 of the second connection pillar 210b is provided smaller than the width W2 of the second element pad 203b. The width WP2 of the second connection pillar 210b may be equal to or greater than ⅕ of the width W2 of the second element pad 203b. The width WP2 of the second connection pillar 210b may be greater than or equal to 106 μm. The width WP2 of the second connection pillar 210b may correspond to the width WP1 of the first connection pillar 210a.

Two second connection pillars 210b may be provided. In this case, the width WP2 of the second connection pillar 210b may be provided to be less than ½ of the width W2 of the second element pad 203b, so that the two second connection pillars 210b are disposed to be spaced apart from each other in the direction of the width W2 of the second element pad 203b.

The second connection pillar 210b may be disposed to face the first connection pillar 210a in the direction in which the first element pad 203a and the second element pad 203b face each other.

The second connection pillar 210b has a predetermined length in a direction of the length L2 of the second element pad 203b. A length of the second connection pillar 210b may be equal to the length L2 of the second element pad 203b. In addition, the length of the second connection pillar 210b may be smaller than the length L2 of the second element pad 203b.

The third connection pillar 210c is coupled to the third element pad 203c. The third connection pillar 210c extends by a predetermined height in an up and down direction from the third element pad 203c. A height h3 of the third connection pillar 210c may be 40 μm to 80 μm. The height h3 of the third connection pillar 210c may correspond to the height h1 of the first connection pillar 210a. The third connection pillar 210c has a predetermined width in a direction of the width W3 of the third element pad 203c. A width WP3 of the third connection pillar 210c is provided smaller than the width W3 of the third element pad 203c. The width WP3 of the third connection pillar 210c may be equal to or greater than ⅕ of the width W3 of the third element pad 203c. The width WP3 of the third connection pillar 210c may be greater than or equal to 60 μm.

Two third connection pillars 210c may be provided. In this case, the width WP3 of the third connection pillar 210c may be provided to be less than ½ of the width W3 of the third element pad 203c, so that the two third connection pillars 210c are disposed to be spaced apart from each other in the direction of the width W3 of the third element pad 203c.

The third connection pillar 210c has a predetermined length in a direction of the length L3 of the third element pad 203c. A length of the third connection pillar 210c may be equal to the length L3 of the third element pad 203c. In addition, the length of the third connection pillar 210c may be smaller than the length L3 of the third element pad 203c.

The fourth connection pillar 210d is coupled to the fourth element pad 203d. The fourth connection pillar 210d extends by a predetermined height in an up and down direction from the fourth element pad 203d. A height h4 of the fourth connection pillar 210d may be 40 μm to 80 μm. The height h4 of the fourth connection pillar 210d may correspond to the height h1 of the first connection pillar 210a. The fourth connection pillar 210d has a predetermined width in a direction of the width W4 of the fourth element pad 203d. A width WP4 of the fourth connection pillar 210d is provided smaller than the width W4 of the fourth element pad 203d. The width WP4 of the fourth connection pillar 210d may be equal to or greater than ⅕ of the width W4 of the fourth element pad 203d.

The width WP4 of the fourth connection pillar 210d may be greater than or equal to 60 μm. The width WP4 of the fourth connection pillar 210d may correspond to the width WP3 of the third connection pillar 210c.

Two fourth connection pillars 210d may be provided. In this case, the width WP4 of the fourth connection pillar 210d may be provided to be less than ½ of the width W4 of the fourth element pad 203d, so that the two fourth connection pillars 210d are disposed to be spaced apart from each other in the direction of the width W4 of the fourth element pad 203d.

The fourth connection pillar 210d may be disposed to face the third connection pillar 210c in the direction in which the third element pad 203c and the fourth element pad 203d face each other.

The fourth connection pillar 210d has a predetermined length in a direction of the length L4 of the fourth element pad 203d. A length of the fourth connection pillar 210d may be the same as the length L4 of the fourth element pad 203d. In addition, the length of the fourth connection pillar 210d may be smaller than the length L4 of the fourth element pad 203d.

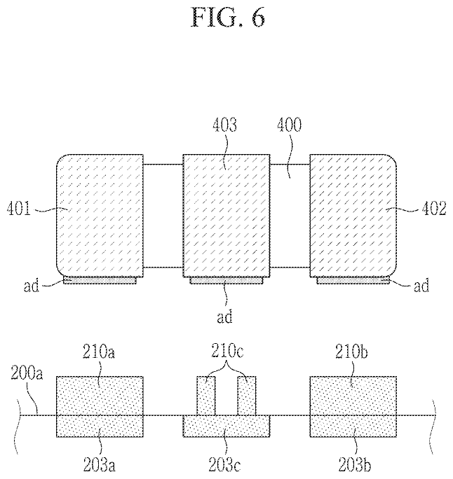

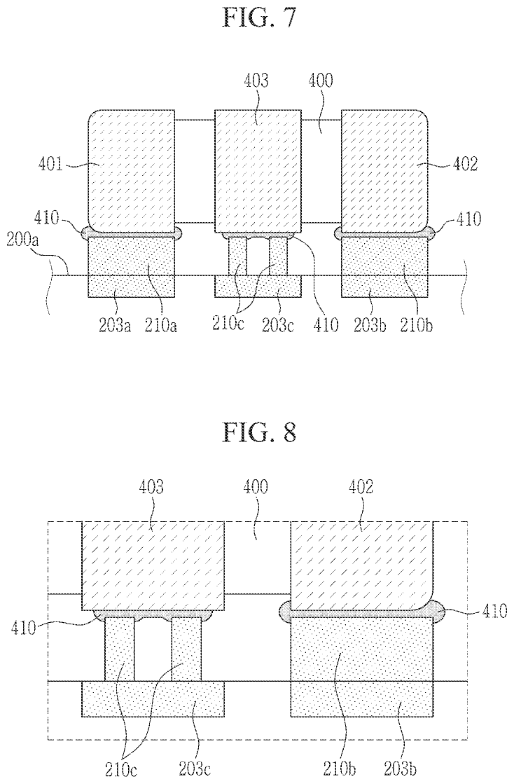

FIG. 6 is a view illustrating an example of a process in which the upper electronic element is connected to the connection pillar, FIG. 7 is a view illustrating an example state in which the upper electronic element is connected to the connection pillar, and FIG. 8 is an enlarged view of an example region where the upper electronic element and the connection pillar are connected.

Referring to FIGS. 6 to 8, the upper electronic element 4a may be connected to the connection pillar 210 through an adhesive material ad. The adhesive material ad may be solder or the like. That is, through surface mounting technology (SMT) or the like, the upper electronic element 4a may be connected to the connection pillar 210 after the adhesive material ad is applied to the electrodes 401, 402, 403, and 404 of the upper electronic element 4a or an end portion of the connection pillar 210. Accordingly, the adhesive material ad forms an adhesive layer 410 at a region where the electrodes 401, 402, 403, and 404 of the upper electronic element 4a and the end portion of the connection pillar 210 are connected to each other. Specifically, a portion of the adhesive material ad may cover a side surface of the end portion of the connection pillar 210 in a process of pressing the upper electronic element 4a in a direction where the connection pillar 210 is disposed, so that the adhesive layer 410 is formed to surround at least a portion of an outer circumference of the upper end portion of the connection pillar 210. In addition, the adhesive layer 410 is disposed at at least a portion of a region where the electrodes 401, 402, 403, and 404 of the upper electronic element 4a and the end portion of the connection pillar 210 face each other in an up and down direction.

In the above-described implementation, a case where the connection pillar 210 is disposed at the upper element pad 203 has been described. Similarly to the above description, the lower element pad 204 may be provided in a structure similar to that of the upper element pad 203, and the connection pillar 210 may extend from the lower element pad 204.

In some implementations, a sufficient distance between the electronic elements 4a and 4b and the substrate 2 may be secured by the connection pillar 210. Accordingly, a space in which liquid may effectively flow is secured between the electronic elements 4a and 4b and the substrate 2. Through this, a flux disposed in a space between the electronic elements 4a and 4b and the substrate 2 may not be removed during a cleaning process. Thus, a phenomenon of splashing of a residual flux during a reflow process may be prevented. In addition, when the molding layer 5 is formed at a region where the electronic elements 4a and 4b are disposed, a material for forming the molding layer may effectively penetrate into the space between the electronic elements 4a and 4b and the substrate 2.

In addition, when two connection pillars 210 spaced apart from each other are provided at the first element pad 203a to the fourth element pad 203d, a space in which liquid may flow between the connection pillars 210 may be secured, and electrical connectivity between the connection pillar 210 and the electronic elements 4a and 4b may be guaranteed.

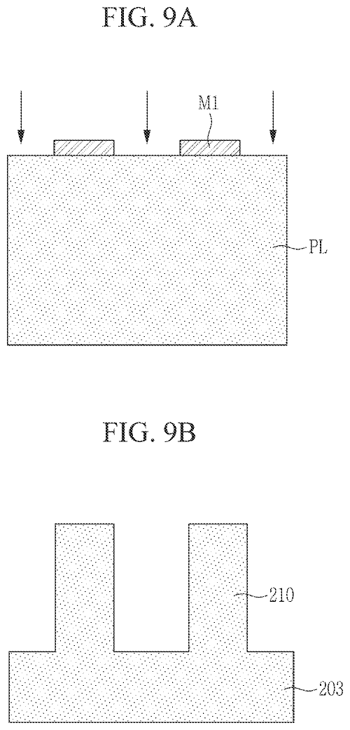

FIGS. 9A and 9B are views illustrating an example of a process of forming the connection pillar at the upper element pad.

Referring to FIGS. 9A and 9B, the connection pillar 210 may be formed through an etching process.

Specifically, in a manufacturing process of the substrate 2, a process pad layer PL is formed at a region where the upper element pad 203 and the connection pillar 210 are formed. A vertical direction thickness of the process pad layer PL may correspond to a sum of a vertical direction thickness of the upper element pad 203 and a height of the connection pillar 210. Thereafter, an etching mask M1 is disposed on an upper surface of the process pad layer PL. The etching mask M1 is disposed to cover a region where the connection pillar 210 is to be formed.

Thereafter, the etching process is performed. Accordingly, the upper element pad 203 is formed at a region where etching is performed, and the connection pillar 210 is formed at a region covered by the etching mask M1. Thereafter, the etching mask M1 is removed.

When the connection pillar 210 is formed through the etching process, the connection pillar 210 may be provided with the same material as the upper element pad 203. In addition, when a cross-section of a region where the upper element pad 203 and the connection pillar 210 are connected is observed through a scanning electron microscope (SEM) photograph or the like, a boundary between the upper element pad 203 and the connection pillar 210 may not be observed.

The connection pillar 210 may also be formed at the lower element pad 204 in the same method as the above-described method.

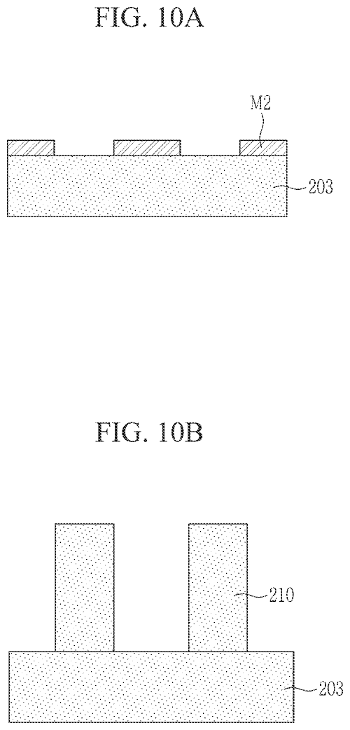

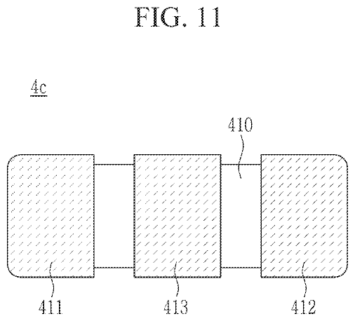

FIGS. 10A and 10B are views illustrating another example of a process of forming the connection pillar at the upper element pad.

Referring to FIGS. 10A and 10B, the connection pillar may be formed through a deposition process.

Specifically, in the manufacturing process of the substrate 2, the upper element pad 203 is formed. Thereafter, a deposition mask M2 is disposed on an upper surface of the upper element pad 203. The deposition mask M2 is disposed in a shape in which a region where the connection pillar 210 is to be formed is opened.

Thereafter, the deposition process is performed. The deposition process may be performed through a plating process or the like. Accordingly, a material deposited on the upper element pad 203 forms the connection pillar 210. Thereafter, the deposition mask M2 is removed.

When the connection pillar 210 is formed through the deposition process, the connection pillar 210 may be made of the same material as the upper element pad 203 or a different material. In addition, when a cross-section of a region where the upper element pad 203 and the connection pillar 210 are connected is photographed and observed through a scanning electron microscope (SEM) or the like, a boundary between the upper element pad 203 and the connection pillar 210 may be partially observed.

The connection pillar 210 may also be formed at the lower element pad 204 in the same method as the above-described method.

FIG. 11 is an example bottom view of the upper electronic element.

Referring to FIG. 11, the upper electronic element 4c includes a body 410, a first electrode 411, a second electrode 412, and a third electrode 413. The upper electronic element 4c may be a capacitor.

The body 410 may be provided with a dielectric material. An internal electrode made of a conductive material may be disposed inside the body 410.

The first electrode 411, the second electrode 412, and the third electrode 413 are attached to an outer surface of the body 410. The first electrode 411, the second electrode 412, and the third electrode 413 are provided with a conductive material. The first electrode 411, the second electrode 412, and the third electrode 413 may be provided with a metallic material.

The first electrode 411 and the second electrode 412 may be disposed to face each other with the body 410 interposed therebetween. The third electrode 413 may be disposed between the first electrode 411 and the second electrode 412. At least some regions of the first electrode 411, the second electrode 412, and the third electrode 413 may be disposed at a bottom surface of the body 410 to be provided so as to vertically face the upper surface of the substrate 2.

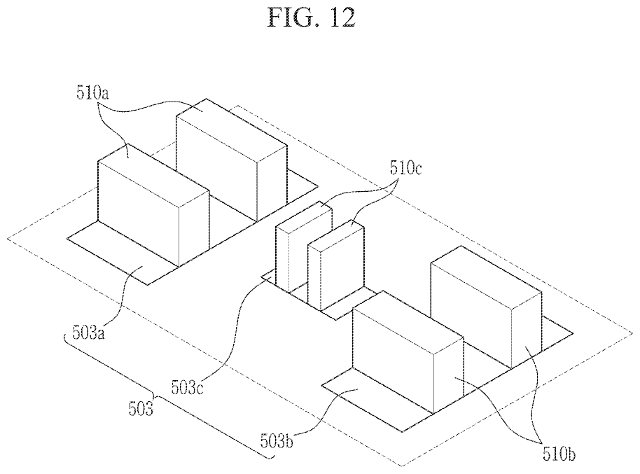

FIG. 12 is an example view showing the upper element pad and the connection pillar.

Referring to FIG. 12, the upper element pad 503 includes a first element pad 503a, a second element pad 503b, and a third element pad 503c.

The first element pad 503a and the second element pad 503b are spaced apart from each other to be disposed facing each other. The first element pad 503a and the second element pad 503b have a predetermined length in directions facing each other. The first element pad 503a and the second element pad 503b have a predetermined width in a direction crossing a direction facing each other. A length of the first element pad 503a may correspond to a length of the second element pad 503b. A width of the first element pad 503a may correspond to a width of the second element pad 503b.

The third element pad 503c is disposed between the first element pad 503a and the second element pad 503b. The third element pad 503c has a predetermined width in a direction in which the first element pad 503a and the second element pad 503b face each other. The third element pad 503c has a predetermined length in a direction crossing a direction in which the first element pad 503a and the second element pad 503b face each other.

An upper surface of the first element pad 503a, an upper surface of the second element pad 503b, and an upper surface of the third element pad 503c may be coplanar with the upper surface 200a of the substrate body 200 adjacent to the first element pad 503a, the second element pad 503b, and the third element pad 503c.

Connection pillars 510a, 510b, and 510c are coupled to the upper element pad 503.

The connection pillars 510a, 510b, and 510c include the first connection pillar 510a, the second connection pillar 510b, and the third connection pillar 510c.

The first connection pillar 510a is coupled to the first element pad 503a. The second connection pillar 510b is coupled to the second element pad 503b. The first connection pillar 510a and the second connection pillar 510b may be provided identically or similarly to the first connection pillar 210a and the second connection pillar 210b described above with reference to FIGS. 4 to 5, respectively. Accordingly, a repeated description is omitted.

The third connection pillar 510c is coupled to the third element pad 503c. The third connection pillar 510c extends by a predetermined height in an up and down direction from the third element pad 503c. A height of the third connection pillar 510c may be 40 μm to 80 μm. The height of the third connection pillar 510c may correspond to a height of the first connection pillar 510a. The third connection pillar 510c has a predetermined width in a direction of a width of the third element pad 503c. A width of the third connection pillar 510c is provided smaller than the width of the third element pad 503c. The width of the third connection pillar 510c may be equal to or greater than ⅕ of the width of the third element pad 503c. The width of the third connection pillar 510c may be greater than or equal to 60 μm.

Two third connection pillars 510c may be provided. In this case, the width of the third connection pillar 510c may be provided to be less than ½ of the width of the third element pad 503c, so that the two third connection pillars 510c are disposed to be spaced apart from each other in the direction of the width of the third element pad 503c.

The third connection pillar 510c has a predetermined length in a direction of a length of the third element pad 503c. A length of the third connection pillar 510c may be the same as the length of the third element pad 503c. In addition, the length of the third connection pillar 510c may be smaller than the length of the third element pad 503c.

The upper electronic element 4c of FIG. 11 may be connected to the upper element pad 503 and the connection pillars 510a, 510b, and 510c. Since a coupling structure of the upper electronic element 4c and the connection pillars 510a, 510b, and 510c is the same as or similar to the structure described above with reference to FIGS. 6 to 8, a repeated description thereof will be omitted.

In addition, the structure described above of FIGS. 11 and 12 may be equally applied to the lower electronic element 4b and the lower element pad 204.

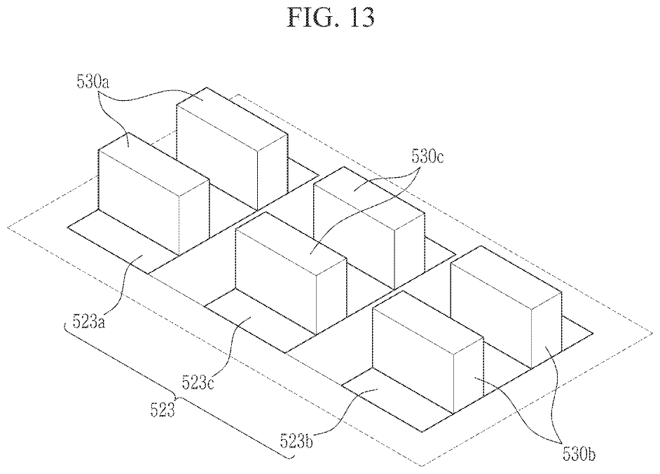

FIG. 13 is another example view showing the upper element pad and the connection pillar.

Referring to FIG. 13, the upper element pad 523 includes a first element pad 523a, a second element pad 523b, and a third element pad 523c.

The first element pad 523a and the second element pad 523b are spaced apart from each other to be disposed facing each other. The first element pad 523a and the second element pad 523b have a predetermined length in directions facing each other. The first element pad 523a and the second element pad 523b have a predetermined width in a direction crossing a direction facing each other. A length of the first element pad 523a may correspond to a length of the second element pad 523b. A width of the first element pad 523a may correspond to a width of the second element pad 523b.

The third element pad 523c is disposed between the first element pad 523a and the second element pad 523b. The third element pad 523c has a predetermined length in a direction in which the first element pad 523a and the second element pad 523b face each other. The third element pad 523c has a predetermined width in a direction crossing a direction in which the first element pad 523a and the second element pad 523b face each other.

An upper surface of the first element pad 523a, an upper surface of the second element pad 523b, and an upper surface of the third element pad 523c may be coplanar with the upper surface 200a of the substrate body 200 adjacent to the first element pad 523a, the second element pad 523b, and the third element pad 523c.

Connection pillars 530a, 530b, and 530c are coupled to the upper element pad 523.

The connection pillars 530a, 530b, and 530c include the first connection pillar 530a, the second connection pillar 530b, and the third connection pillar 530c.

The first connection pillar 530a is coupled to the first element pad 523a. The second connection pillar 530b is coupled to the second element pad 523b. The first connection pillar 530a and the second connection pillar 530b may be provided identically or similarly to the first connection pillar 210a and the second connection pillar 210b described above with reference to FIGS. 4 to 5, respectively. Accordingly, a repeated description is omitted.

The third connection pillar 530c is coupled to the third element pad 523c. The third connection pillar 530c extends by a predetermined height in an up and down direction from the third element pad 523c. A height of the third connection pillar 530c may be 40 μm to 80 μm. The height of the third connection pillar 530c may correspond to a height of the first connection pillar 530a. The third connection pillar 530c has a predetermined width in a direction of a width of the third element pad 523c. A width of the third connection pillar 530c is provided smaller than the width of the third element pad 523c. The width of the third connection pillar 530c may be equal to or greater than ⅕ of the width of the third element pad 523c. The width of the third connection pillar 530c may be greater than or equal to 106 μm.

Two third connection pillars 530c may be provided. In this case, the width of the third connection pillar 530c may be provided to be less than ½ of the width of the third element pad 523c, so that the two third connection pillars 530c are disposed to be spaced apart from each other in the direction of the width of the third element pad 523c.

The third connection pillar 530c has a predetermined length in a direction of a length of the third element pad 523c. A length of the third connection pillar 530c may be the same as the length of the third element pad 523c. In addition, the length of the third connection pillar 530c may be smaller than the length of the third element pad 523c.

The upper electronic element 4c of FIG. 11 may be connected to the upper element pad 523 and the connection pillars 530a, 530b, and 530c. Since a coupling structure of the upper electronic element 4c and the connection pillars 530a, 530b, and 530c is the same as or similar to the structure described above with reference to FIGS. 6 to 8, a repeated description thereof will be omitted.

In addition, the structure described above of FIGS. 11 and 13 may be equally applied to the lower electronic element 4b and the lower element pad 204.

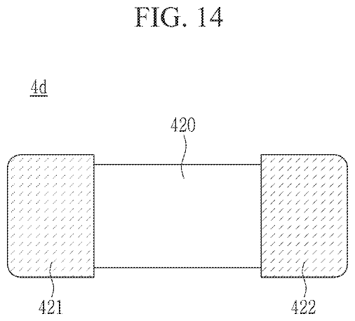

FIG. 14 is another example bottom view of the upper electronic element.

Referring to FIG. 14, the upper electronic element 4d includes a body 420, a first electrode 421, and a second electrode 422. The upper electronic element 4d may be a capacitor.

The body 420 may be provided with a dielectric material. An internal electrode made of a conductive material may be disposed inside the body 420.

The first electrode 421 and the second electrode 422 are attached to an outer surface of the body 420. The first electrode 421 and the second electrode 422 are provided with a conductive material. The first electrode 421 and the second electrode 422 may be provided with a metallic material.

The first electrode 421 and the second electrode 422 may be disposed to face each other with the body 420 interposed therebetween. At least some regions of the first electrode 421 and the second electrode 422 may be disposed at a bottom surface of the body 420 to be provided so as to vertically face the upper surface of the substrate 2.

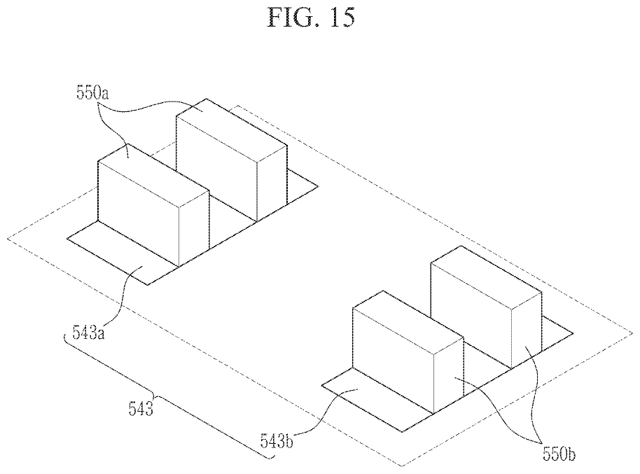

FIG. 15 is another example view showing the upper element pad and the connection pillar.

Referring to FIG. 15, the upper element pad 543 includes a first element pad 543a and a second element pad 543b.

The first element pad 543a and the second element pad 543b are spaced apart from each other to be disposed facing each other. The first element pad 543a and the second element pad 543b have a predetermined length in directions facing each other. The first element pad 543a and the second element pad 543b have a predetermined width in a direction crossing a direction facing each other. A length of the first element pad 543a may correspond to a length of the second element pad 543b. A width of the first element pad 543a may correspond to a width of the second element pad 543b.

An upper surface of the first element pad 543a and an upper surface of the second element pad 543b may be coplanar with the upper surface 200a of the substrate body 200 adjacent to the first element pad 543a and the second element pad 543b.

Connection pillars 550a and 550b are coupled to the upper element pad 543.

The connection pillars 550a and 550b include the first connection pillar 550a and the second connection pillar 550b. The first connection pillar 550a is coupled to the first element pad 543a. The second connection pillar 550b is coupled to the second element pad 543b. The first connection pillar 550a and the second connection pillar 550b may be provided identically or similarly to the first connection pillar 210a and the second connection pillar 210b described above with reference to FIGS. 4 and 5, respectively. Accordingly, a repeated description is omitted.

The upper electronic element 4d of FIG. 14 may be connected to the upper element pad 203 and the connection pillar 210. Since a coupling structure of the upper electronic element 4d and the connection pillar 210 is the same as or similar to the structure described above with reference to FIGS. 6 to 8, a repeated description thereof will be omitted.

In addition, the structure described above of FIGS. 14 and 15 may be equally applied to the lower electronic element 4b and the lower element pad 204.

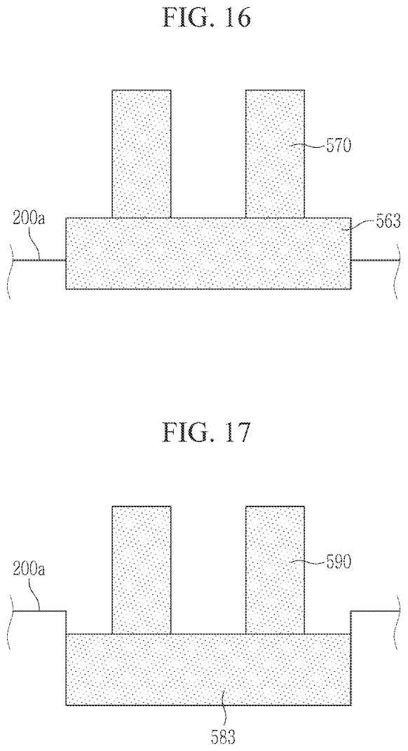

FIG. 16 is another example view showing the upper element pad and the connection pillar.

Referring to FIG. 16, an upper surface of the upper element pad 563 may protrude from the upper surface 200a of the substrate body 200 adjacent to the upper element pad 563. Accordingly, the upper surface of the upper element pad 563 may be disposed above the upper surface 200a of the substrate body 200 adjacent to the upper element pad 563.

Since a structure of the upper element pad 563, a connection pillar 570 coupled to the upper element pad 563, and like are the same as or similar to the structure described above with reference to FIGS. 4 to 10, 12, 13, and 15, a repeated description thereof will be omitted.

In addition, the structure described above with reference to FIG. 16 may be equally or similarly applied to the lower electronic element 4b and the lower element pad 204.

FIG. 17 is another example view showing the upper element pad and the connection pillar.

Referring to FIG. 17, an upper surface of the upper element pad 583 may be disposed to enter toward a central region of the substrate body 200 in a vertical direction than the upper surface 200a of the substrate body 200 adjacent to the upper element pad 583. Accordingly, the upper surface of the upper element pad 583 may be disposed below the upper surface 200a of the substrate body 200 adjacent to the upper element pad 583.

Since a structure of the upper element pad 583, a connection pillar 590 coupled to the upper element pad 583, and like are the same as or similar to the structure described above with reference to FIGS. 4 to 10, 12, 13, and 15, a repeated description thereof will be omitted.

In addition, the structure described above with reference to FIG. 17 may be equally or similarly applied to the lower electronic element 4b and the lower element pad 204.

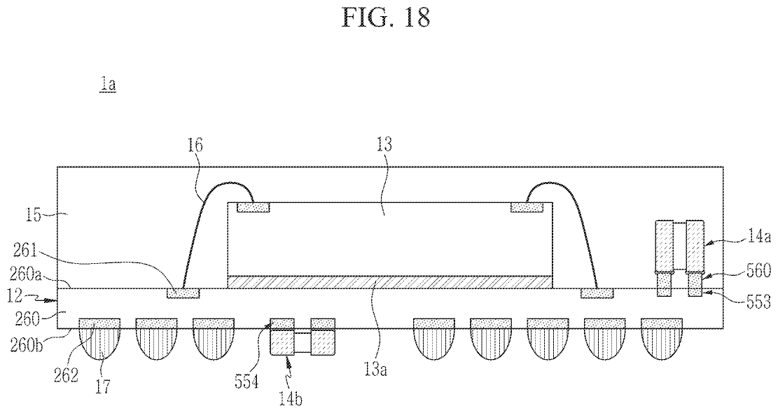

FIG. 18 is a cross-sectional view of an example of a semiconductor package.

Referring to FIG. 18, the semiconductor package 1a includes a substrate 12, a semiconductor chip 13, electronic elements 14a and 14b, and a molding layer 15.

The substrate 12 may connect the semiconductor chip 13 and the like to the outside. The substrate 12 has a first surface and a second surface disposed opposite each other in opposite directions. Hereinafter, the first surface of the substrate 12 is referred to as an upper surface of the substrate 12, and the second surface of the substrate 12 is referred to as a lower surface of the substrate 12.

The substrate 12 includes a substrate body 260, an upper pad 261, a connection pad 262, and element pads 553 and 554.

The substrate body 260 may include an insulating material. The substrate body 260 has a first surface 260a and a second surface 260b disposed to face each other in opposite directions. In order to correspond to the substrate 12, the first surface 260a of the substrate body 260 may be an upper surface 260a of the substrate body 260, and the second surface 260b of the substrate body 260 may be a lower surface 260b of the substrate body 260.

The upper pad 261 is disposed at an upper end portion of the substrate body 260. The upper pad 261 may be provided to be exposed to an outer space of the substrate 12. The upper pad 261 is provided with a conductive material. The upper pad 261 may be provided with a metallic material.

The connection pad 262 is disposed at a lower end portion of the substrate body 260. The connection pad 262 is provided to be exposed to an outer space of the substrate 12. The connection pad 262 is provided with a conductive material. The connection pad 262 may be provided with a metallic material. A connection terminal 17 may be coupled to the connection pad 262. The connection terminal 17 may be a solder ball or the like.

The element pads 553 and 554 include the upper element pad 553 and the lower element pad 554. The upper element pad 553 is disposed at an upper end portion of the substrate body 260. The upper element pad 553 is provided with a conductive material. The upper element pad 553 may be provided with a metallic material. A connection pillar 560 is coupled to the upper element pad 553.

The lower element pad 554 is disposed at a lower end portion of the substrate body 260. The lower element pad 554 may be provided to be exposed to an outer space of the substrate 12. The lower element pad 554 is provided with a conductive material. The lower element pad 554 may be provided with a metallic material.

The semiconductor chip 13 may be disposed at an upper surface of the substrate 12. The semiconductor chip 13 may be attached to the upper surface of the substrate 12 by a chip adhesive layer 13a. The semiconductor chip 13 may be connected to the upper pad 261 by a bonding wire 16.

The electronic elements 14a and 14b are disposed at at least one of the upper and lower surfaces of the substrate 12. Each of the electronic elements 14a and 14b may be a passive element. Each of the electronic elements 14a and 14b may be a capacitor. The electronic elements 14a and 14b may include the upper electronic element 14a and the lower electronic element 14b.

The molding layer 15 may be formed at the upper surface of the substrate 12. The molding layer 15 may be formed to surround the outside of the semiconductor chip 13. In addition, the molding layer 15 may be formed to surround the outside of the upper electronic element 14a.

The upper electronic element 14a, the upper element pad 553, and the connection pillar 560 may be the same as or similar to the upper electronic element 4a, 4c, or 4d, the upper element pad 203, 503, 523, 543, 563, or 583, and the connection pillar 210, 510a, 510b, 510c, 530a, 530b, 530c, 550a, 550b, 570, or 590 described above with reference to FIGS. 3 to 17. Accordingly, a repeated description is omitted.

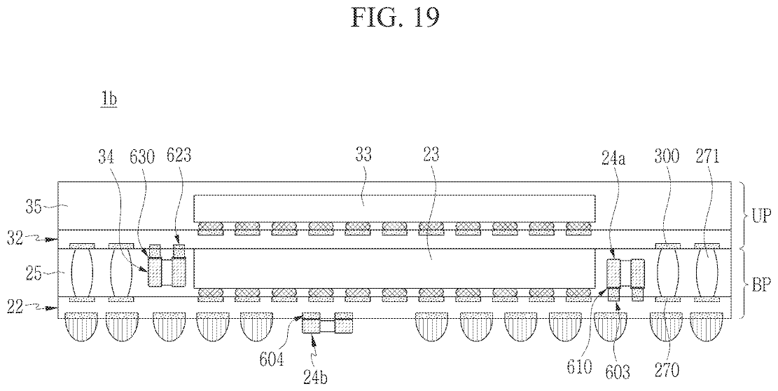

FIG. 19 is a cross-sectional view of another example of a semiconductor package.

Referring to FIG. 19, the semiconductor package 1b includes a lower package portion BP and an upper package portion UP.

The lower package portion BP includes a substrate 22, a semiconductor chip 23, electronic elements 24a and 24b, and a molding layer 25.

An upper connection pad 270 and an upper element pad 603 may be disposed at an upper surface of the substrate 22. A connection pillar 610 is coupled to the upper element pad 603. A lower element pad 604 may be disposed at a lower surface of the substrate 22.

The substrate 22, the semiconductor chip 23, the electronic elements 24a and 24b, and the molding layer 25 may be the same as or similar to the semiconductor package 1 of FIG. 1 or the semiconductor package 1b of FIG. 18. In addition, the upper electronic element 24a, the upper element pad 603, and the connection pillar 610 may be the same as or similar to the upper electronic element 4a, 4c, or 4d, the upper element pad 203, 503, 523, 543, 563, or 583, and the connection pillar 210, 510a, 510b, 510c, 530a, 530b, 530c, 550a, 550b, 570, or 590 described above with reference to FIGS. 3 to 17. Accordingly, a repeated description is omitted.

The upper package portion UP is disposed on the lower package portion BP. The upper package portion UP includes an upper substrate 32, an upper semiconductor chip 33, a passive element 34, and an upper molding layer 35. The upper connection pad 270 disposed at the upper surface of the substrate 22 and a connection pad 300 disposed at a lower surface of the upper substrate 32 may be connected by a connection pillar 271.

A passive element pad 623 may be disposed at a bottom surface of the upper substrate 32. An element connection pillar 630 is coupled to the passive element pad 623. The passive element 34 is connected to the element connection pillar 630. The passive element 34 may be a capacitor. The passive element 34, the passive element pad 623, and the element connection pillar 630 may be the same as or similar to the upper electronic element 4a, 4c, or 4d, the upper element pad 203, 503, 523, 543, 563, or 583, and the connection pillar 210, 510a, 510b, 510c, 530a, 530b, 530c, 550a, 550b, 570, or 590 described above with reference to FIGS. 3 to 17. However, there is a difference in that the passive element 34, the passive element pad 623, and the element connection pillar 630 are disposed below or on a lower surface of the upper substrate 32 so that a vertical direction regarding the passive element 34, the passive element pad 623, and the element connection pillar 630 is reversed. Accordingly, a repeated description is omitted.

The upper semiconductor chip 33 may be mounted above or on the upper substrate 32. The upper semiconductor chip 33 may be connected to the upper substrate 32 through a chip terminal disposed at a lower surface of the upper semiconductor chip 33 similarly to the semiconductor chip 3 of FIG. 1. In addition, the upper semiconductor chip 33 may be connected to the upper substrate 32 through a bonding wire similarly to the semiconductor chip 13 of FIG. 18.

The upper molding layer 35 may be formed on an upper surface of the upper substrate 32. The upper molding layer 35 may be formed to surround the outside of the upper semiconductor chip 33.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the present disclosure has been described in connection with some implementations, it is to be understood that the disclosure is not limited to the disclosed implementations, but, on the contrary, is intended to cover various modifications and equivalent arrangements included within the spirit and scope of the appended claims.

### DESCRIPTION OF SYMBOLS

2: substrate
3: semiconductor chip
4a: upper electronic element
4b: lower electronic element
5: molding layer
6: chip terminal
7: connection terminal
203: upper element pad
204: lower element pad
210: connection pillar
400: body
401: first electrode
402: second electrode
403: third electrode
404: fourth electrode
410: adhesive layer

What is claimed is:

1. A semiconductor package comprising:
a substrate that includes a first surface and a second surface disposed in an opposite direction of the first surface;
a semiconductor chip that is disposed at the first surface of the substrate; and
an electronic element that is disposed at a first surface of the substrate, wherein the substrate includes a first element pad disposed at the first surface, a second element pad disposed at the first surface as the first element pad, a first connection pillar extending from the first element pad, a second connection pillar extending from the second element pad, and the electronic element is connected to the first connection pillar and the second connection pillar.

2. The semiconductor package of claim 1, further comprising an adhesive layer disposed at a region where the electronic element and the first connection pillar are connected and a region where the electronic element and the second connection pillar are connected.

3. The semiconductor package of claim 2, wherein the adhesive layer is disposed at at least a portion of a region where the electronic element faces the first connection pillar and at least a portion of a region where the electronic element faces the second connection pillar.

4. The semiconductor package of claim 1, wherein the semiconductor package includes an additional first connection pillar and an additional second connection pillar.

5. The semiconductor package of claim 4, wherein the two first connection pillars are separated from the two second connection pillars in a direction crossing a direction in which the first element pad faces the second element pad.

6. The semiconductor package of claim 1, wherein the substrate further includes a third element pad disposed at the same surface as the first element pad, a fourth element pad disposed at the same surface as the first element pad, a third connection pillar extending from the third element pad, and a fourth connection pillar extending from the fourth element pad.

7. The semiconductor package of claim 6, wherein at least some regions of the third element pad and the fourth element pad are disposed at a region between the first element pad and the second element pad.

8. The semiconductor package of claim 6, wherein a direction in which the third element pad faces the fourth element pad crosses a direction in which the first element pad faces the second element pad.

9. The semiconductor package of claim 6, wherein the semiconductor package includes an additional third connection pillar and an additional fourth connection pillar.

10. The semiconductor package of claim 9, wherein the two third connection pillars are separated from the two fourth connection pillars in a direction crossing a direction in which the third element pad faces the fourth element pad.

11. The semiconductor package of claim 6, wherein a height at which the second connection pillar extends, a height at which the third connection pillar extends, and a height at which the fourth connection pillar extends correspond to a height at which the first connection pillar extends.

12. The semiconductor package of claim 11, wherein each of the height at which the first connection pillar extends, the height at which the second connection pillar extends, the height at which the third connection pillar extends, and the height at which the fourth connection pillar extends is 40 μm to 80 μm.

13. The semiconductor package of claim 1, wherein the substrate further includes a third element pad, disposed between the first element pad and the second element pad, and a third connection pillar extending from the third element pad.

14. A semiconductor package comprising:
a substrate;
a semiconductor chip disposed at a top surface of the substrate; and
an electronic element disposed at the top surface of the substrate, wherein the substrate includes a first element pad disposed at the top surface, a second element pad disposed at the top surface, a third element pad disposed at the top surface, a fourth element pad disposed at the top surface, and at least one connection pillar extending from the first element pad, the second element pad, the third element pad, and the fourth element pad, and the electronic element is connected to the connection pillar.

15. The semiconductor package of claim 14, further comprising an adhesive layer disposed at a region where the electronic element and the at least one connection pillar are connected.

16. The semiconductor package of claim 14, wherein the at least one connection pillar comprises a same material as the first element pad, the second element pad, the third element pad, and the fourth element pad.

17. The semiconductor package of claim 14, wherein a direction in which the first element pad faces the second element pad crosses a direction in which the third element pad faces the fourth element pad.

18. A substrate for a package, the substrate comprising:
a pad connecting a semiconductor chip; and
an element pad connecting an electronic element,
wherein the element pad includes a first element pad, a second element pad disposed at a same surface as the first element pad, a first connection pillar extending from the first element pad, and a second connection pillar extending from the second element pad.

19. The substrate of claim 18, further comprising:
a third element pad disposed at the same surface as the first element pad;
a fourth element pad disposed at the same surface as the first element pad;
a third connection pillar extending from the third element pad; and
a fourth connection pillar extending from the fourth element pad.

20. The substrate of claim 19, wherein a direction in which the first element pad faces the second element pad crosses a direction in which the third element pad faces the fourth element pad.
